(19) United States
(12) Patent Application Publication
(10) Pub. No.: US 2017/0112017 A1
(43) Pub. Date: Apr. 20, 2017

(54) HEAT DISSIPATING SYSTEM

(71) Applicant: COOLER MASTER CO., LTD., NEW TAIPEI CITY (TW)

(72) Inventor: Yao-chun WANG, NEW TAIPE (TW)

(21) Appl. No.: 15/139,639

(22) Filed: Apr. 27, 2016

(30) Foreign Application Priority Data
Oct. 20, 2015 (CN) 201520788566.5

(51) Int. Cl. H05K 7/20; F28D 15/06; F28D 15/02

(52) U.S. Cl. CPC H05K 7/208; F28D 15/0266; F28D 15/0275; F28D 15/025; F28D 15/06

(57) ABSTRACT

A heat dissipating system provided herein comprises a cooling tank for storing a cooling liquid and a heat element, wherein the cooling liquid is phase-changed into a working gas due to thermal energy generated by the heat element; an evaporator installed in the cooling tank for absorbing thermal energy of the working gas; a condenser uncovered by the cooling tank; at least one communicating member communicated with the evaporator and the condenser and filled with a coolant, wherein the coolant is heated in the evaporator and flows to the condenser through the communicating member in a gaseous state, and, after being cooled in the condenser, recovers into a liquid state and then returns to the evaporator through the communicating member; and a first gas driving module for driving air to flow around the condenser.

### FIELD OF THE INVENTION

The present invention relates to a heat dissipating system. Specifically, the present invention relates to a heat dissipating system applied on a heat element.

### BACKGROUND OF THE INVENTION

Please refer to FIG. 1, which is a functional block diagram of a conventional heat dissipating system applied on a data center, wherein a plurality of mainboards 11 of a server are disposed in a cooling tank having a dielectric cooling liquid 100 with a boiling point between 40 to 60° C., such as the Novec Engineered Fluids produced by 3M. Accordingly, a temperature at which the server normally operates would result in boiling of the dielectric cooling liquid 100 characterized in electrical insulation in the cooling tank 10. The boiled dielectric cooling liquid 100 is vaporized, collected through the upper cover 101 and the vapor trapper 102, returned into the liquid state from the gaseous state by the condenser 12, and finally flows back to the semi-opened cooling tank 10. In the conventional technique, a huge host 13 having a great amount of cooling water is disposed at outdoors to provide a water cycling to the condenser 12 to take away the thermal energy in the dielectric cooling liquid 100 so that the dielectric cooling liquid 100 could be condensed by the condenser 12. However, the flexibility of space arrangement is difficult since a certain amount of space is required for the huge host 13 and it is hard to move the pipelines for transmitting cooling water.

### SUMMARY OF THE INVENTION

Therefore, one subject of the present invention is to provide a heat dissipating system which overcomes the technique drawbacks mentioned above.

In one aspect, the present invention provides a heat dissipating system, which stores a cooling liquid and dissipates heat generated from a heat element immersed in the cooling liquid, comprising: a cooling tank for storing the cooling liquid and containing the heat element, wherein the cooling liquid is phase-changed into a working gas due to thermal energy generated by the heat element; an evaporator installed in the cooling tank for absorbing thermal energy of the working gas; a condenser uncovered by the cooling tank; at least one communicating member communicated with the evaporator and the condenser and filled with a coolant, wherein the coolant is heated in the evaporator and flows to the condenser through the communicating member in a gaseous state, and, after being cooled in the condenser, recovers into a liquid state and then returns to the evaporator through the communicating member; and a first gas driving module for driving air to flow around the condenser.

In another aspect, the present invention provides a heat dissipating system, which stores a cooling liquid and dissipates heat generated from a heat element immersed in the cooling liquid, comprising: a cooling tank for storing the cooling liquid and containing the heat element, wherein the cooling liquid is phase-changed into a working gas due to thermal energy generated by the heat element; an evaporator installed in the cooling tank for absorbing thermal energy of the working gas; a condenser uncovered by the cooling tank; at least one communicating member communicated with the evaporator and the condenser and filled with a coolant, wherein the coolant is heated in the evaporator and flows to the condenser through the communicating member in a gaseous state, and, after being cooled in the condenser, recovers into a liquid state and then returns to the evaporator through the communicating member; and a second gas driving module disposed in the cooling tank to drive the working gas to flow in the cooling tank.

According to the technique solutions above, the heat element in one embodiment of the present invention comprises a circuit module, and the cooling liquid is a dielectric cooling liquid.

According to the technique solutions above, the condenser in one embodiment of the present invention is a heat pipe, which is disposed at a side of the evaporator, extended at outside of the cooling tank and uncovered by the cooling tank, wherein the coolant in the heat pipe is phase-changed into the gaseous state and flows to outside of the cooling tank after absorbing thermal energy from the evaporator, and is phase-changed into the liquid state and flows to a section near the evaporator after dissipating heat energy to air.

According to the technique solutions above, the heat dissipating system in one embodiment of the present invention further comprises a temperature sensor for, in accordance with a temperature measured by the temperature sensor, determining whether to turn on the first gas driving module or the second gas driving module, or adjusting a rotation speed of the first gas driving module or the second gas driving module.

The heat dissipating system in the present invention can be integrated on a cooling tank so that the space necessary for the heat dissipating system is smaller than before and can be flexibly arranged, and the heat dissipating system is easy to move. Furthermore, the heat dissipating system in the present invention keeps great heat dissipating and energy saving efficiency through temperature monitoring and fans controlling.

### BRIEF DESCRIPTION OF THE DRAWINGS

FIG. 1 is a functional block diagram of a conventional heat dissipating system applied on a data center.

FIG. 2 is a functional block diagram of a heat dissipating system according to one embodiment of the present invention.

FIG. 3 is a schematic diagram of a heat pipe of the condenser according to one embodiment of the present invention.

FIG. 4 is a functional block diagram of a control circuit for controlling air fans according to one embodiment of the present invention.

FIG. 5 is a flow diagram of a fan control method performed by the control circuit shown in FIG. 4 according to one embodiment of the present invention.

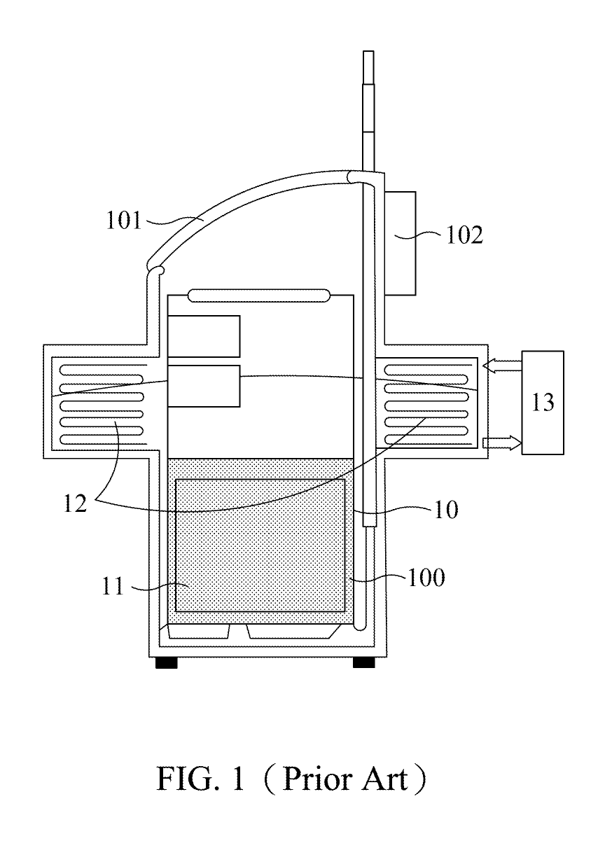

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

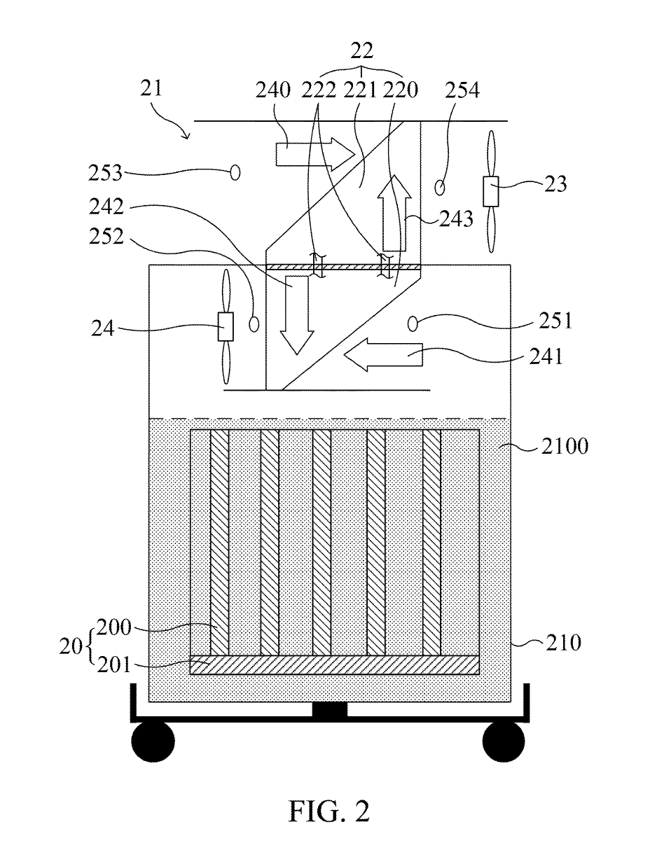

Please refer to FIG. 2, which is a functional block diagram of a heat dissipating system according to one embodiment of the present invention. The heat dissipating system 21 could be widely applied on any kinds of heat element, especially for those circuit modules such as the data center 20 comprising a server with a plurality of mainboards 200 and a backboard 201 shown in this figure. The heat dissipating system 21 in this embodiment primarily comprises a cooling tank 210. The cooling tank 210 is used for storing a cooling liquid 2100 and disposing the data center 20. In one embodiment, the cooling liquid 2100 could be a dielectric cooling liquid 100 with a boiling point at a temperature around which the data center 20 normally operates, such as the Novec Engineered Fluids produced by 3M, whose boiling point is between 40 to 60° C. Accordingly, the data center 20 could be fully immersed in the cooling liquid 2100 while the electric circuit in the data center 20 is operated normally. It is noted that, it also works when only a part of the data center 20, i.e. the part generating thermal energy, is immersed in the cooling liquid 2100.

The cooling liquid 2100 is phase-changed into a working gas after absorbing the thermal energy generated from the data center 20, and the working gas flows upwards to the heat exchanger 22 disposed in the heat dissipating system 21 of this embodiment. The heat exchanger 22 primarily comprises an evaporator 220 and a condenser 221, wherein the evaporator 220 is disposed inside the cooling tank 210 in order to absorb the thermal energy of the working gas so that, after the thermal energy of the working gas is absorbed, the working gas is phase-changed back to the cooling liquid 2100 and flows back to the cooling tank 210; the condenser 221 is disposed at a side of the evaporator 220, extended at outside of the cooling tank 210 and uncovered by the cooling tank 210; and a communicating member 222 is connected between the evaporator 220 and the condenser 221 and is communicated with the evaporator 220 and the condenser 221. The communicating member 222 is filled with a coolant (not shown in this figure), wherein the coolant flows to the condenser 221 through the communicating member 222 along a direction 243 in a gaseous state after absorbing the thermal energy from the evaporator 220, and returns to the evaporator 220 through the communicating member 222 along a direction 242 in a liquid state after cooling by the condenser 221. Accordingly, the thermal energy of the evaporator 220 could be absorbed and transmitted to outside of the cooling tank 210 by the condenser 221. In order to improve the efficiency of heat dissipation, a first gas driving module 23 is disposed around the condenser 221 at outside of the cooling tank 210 to drive the air to rapidly flow around the condenser 221 along a direction 240 in this embodiment. Furthermore, a second gas driving module 24 is disposed in the cooling tank 210 to drive the working gas to flow along a direction 241 for improving the efficiency of phase-changing the working gas to the cooling liquid 2100 followed by returning the cooling liquid 2100 to the cooling tank 210. For example, the boiling point of the dielectric cooling liquid used in this embodiment is 61° C., the temperature measured at the position 251 is about 51° C., and the temperature measured at the position 252 is decreased to about 33° C. because of the evaporator 220. When the temperature of the air measured at the position 253 is about 25° C., the temperature measured at the position 254 would be increased to about 37° C. because of heat dissipation of the condenser 221. The first gas driving module 23 and the second gas driving module 24 could be accomplished by using fans or other air flow regulators. Furthermore, in the conventional art, when the cooling tank 210 is opened in order to change a broken mainboard 200, the cooling liquid 2100 would be vaporized as the working gas and then dissipated into the air at outside of the cooling tank 210 because the power of the server is kept at ON state so that the server is continuously operated and the thermal energy is generated accordingly. The present invention prevents most of the working gas from dissipating into the air at outside of the cooling tank 210 because an air wall is formed on a path through which the working gas might flow to the air at outside of the cooling tank 210 by forcing the working gas to flow at a specific direction by operating the second gas driving module 24.

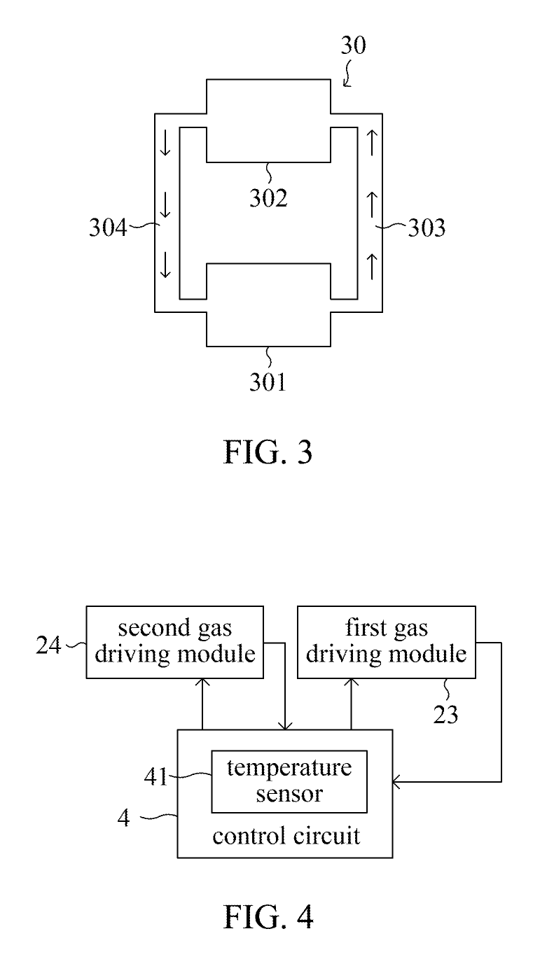

In one embodiment of the present invention, the cooling tank 210 is a sealed tank and only the signal lines (not shown in this figure) communicating between the data center 20 and outside elements could penetrate through the cooling tank, so that dissipation of the cooling liquid 2100 can be prevented. The condenser 221 disposed at outside of the liquid tank 210 could be a heat pipe. The heat pipe is disposed at a side of the evaporator 220, extended at outside of the cooling tank 210 and uncovered by the cooling tank 210, and the structural schematic diagram of the heat pipe is shown in FIG. 3. An evaporating part 301 of the heat pipe 30 contacts to the evaporator 220 of the cooling tank 210, or the evaporating part 301 and the evaporator 220 are formed in one piece. After absorbing the thermal energy from the evaporator 220, the coolant in the evaporating part 301 phase-changes into a gaseous state, moves to a condensing part 302 at outside of the liquid tank 210 through the communicating member 303 communicated between the evaporating part 301 and the condensing part 302, phase-changes back to the liquid state after dissipating heat to the air flowing around, and then flows back to the evaporating part 301 close to the evaporator 220 through the communicating member 304 communicated between the condensing part 302 and the evaporating part 301. In one embodiment, the communicating member 304 is accomplished by using thermosyphons, in which the liquid flows back to the evaporating part 301 due to gravity. In another embodiment, the communicating member 304 is accomplished by using a wick-type heat pipe and the liquid is returned to the evaporating part 301 through the capillary structure therein.

Furthermore, in order to balance the heat dissipating efficiency and the energy saving, a control circuit 4 as shown in FIG. 4 for controlling the air fans is disposed in the heat dissipating system in one embodiment of the present invention. The temperature sensor 41 in the control circuit 4 is used for measuring the temperature inside the cooling tank 210, for example: the positions 251˜254, to determine whether the heat dissipating efficiency is matched with the thermal energy generated from the heat element, and for determining whether to turn on the air fans or adjusting a rotation speed of the air fans in accordance with the temperature measured by the temperature sensor 41. As shown in FIG. 4, in the present embodiment, a value of a working voltage supplied to the first gas driving module 23 and the second gas driving module 24 is controlled according to the temperature measured by the temperature sensor 41, so that whether to turn on the air fans or how the rotation speed of the air fans being adjusted can be determined accordingly. Furthermore, the control circuit 4 could read the value of the working voltage to determine whether the air fans are normal, so that a warning message could be sent or another air fan could be activated when one of the air fans is broken.

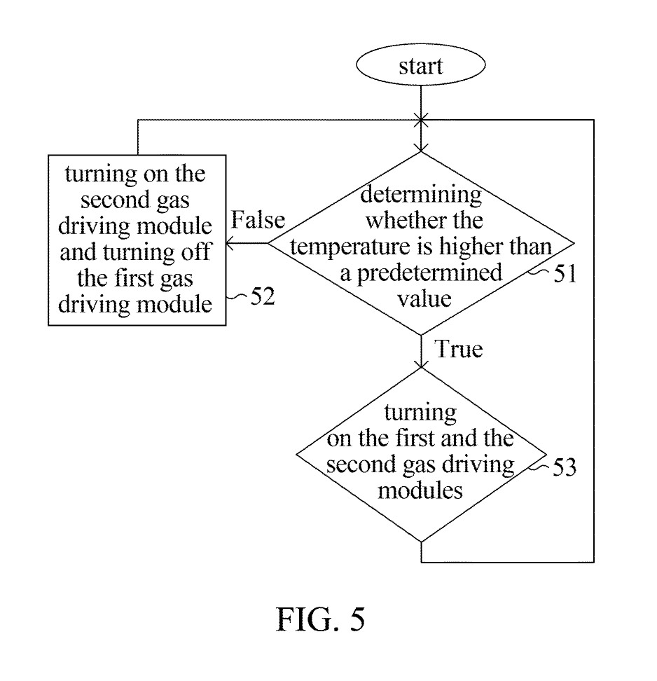

Please refer to FIG. 5, which is a flow diagram of a fan control method performed by the control circuit shown in FIG. 4 according to one embodiment of the present invention. Firstly, the temperature is measured, and it is determined that whether the temperature is higher than a predetermined value in the step 51. When the temperature is not higher than the predetermined value (a result of the determination in step 51 is “False”), it is known that the cooling system is not in a high-temperature state, and the step 52 is performed to turn on the second gas driving module 24 and turn off the first gas driving module 23 to dissipate heat and save power at the same time. On the contrary, when the measured temperature is higher than the predetermined value (the result of the determination in step 51 is “True”), it is known that the cooling system is in the high-temperature state, and the step 53 is performed to turn on both the first gas driving module 23 and the second gas driving module 24 to enhance the ability of heat dissipation. Therefore, the first gas driving module 23 and the second gas driving module 24 can be turned on or off according to actual requirement.

In summary, the heat dissipating system in the present invention can be integrated with a cooling tank so that the space necessary for the heat dissipating system is smaller than before and can be flexibly arranged, and the heat dissipating system is easy to move. Furthermore, the heat dissipating system in the present invention can be widely applied to kinds of ICs or electronic apparatuses requiring heat dissipation, and great heat dissipating and energy saving efficiency can be kept through temperature monitoring and fans controlling. While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat dissipating system, which stores a cooling liquid and dissipates heat generated from a heat element immersed in the cooling liquid, comprising:
a cooling tank for storing the cooling liquid and containing the heat element, wherein the cooling liquid is phase-changed into a working gas due to thermal energy generated by the heat element;
an evaporator installed in the cooling tank for absorbing thermal energy of the working gas;
a condenser uncovered by the cooling tank;
at least one communicating member communicated with the evaporator and the condenser and filled with a coolant, wherein the coolant is heated in the evaporator and flows to the condenser through the communicating member in a gaseous state, and, after being cooled in the condenser, recovers into a liquid state and then returns to the evaporator through the communicating member; and
a first gas driving module for driving air to flow around the condenser.

2. The heat dissipating system according to claim 1, wherein the heat element comprises a circuit module, and the cooling liquid is a dielectric cooling liquid.

3. The heat dissipating system according to claim 1, wherein the at least one communicating member is a heat pipe.

4. The heat dissipating system according to claim 1, further comprising a second gas driving module disposed in the cooling tank to drive the working gas to flow in the cooling tank.

5. The heat dissipating system according to claim 4, further comprising a temperature sensor for, in accordance with a temperature measured by the temperature sensor, determining whether to turn on the first gas driving module or the second gas driving module, or adjusting a rotation speed of the first gas driving module or the second gas driving module.

6. A heat dissipating system, which stores a cooling liquid and dissipates heat generated from a heat element immersed in the cooling liquid, comprising:
a cooling tank for storing the cooling liquid and containing the heat element, wherein the cooling liquid is phase-changed into a working gas due to thermal energy generated by the heat element;
an evaporator installed in the cooling tank for absorbing thermal energy of the working gas;
a condenser uncovered by the cooling tank;
at least one communicating member communicated with the evaporator and the condenser and filled with a coolant, wherein the coolant is heated in the evaporator and flows to the condenser through the communicating member in a gaseous state, and, after being cooled in the condenser, recovers into a liquid state and then returns to the evaporator through the communicating member; and
a second gas driving module disposed in the cooling tank to drive the working gas to flow in the cooling tank.

7. The heat dissipating system according to claim 6, wherein the heat element comprises a circuit module, and the cooling liquid is a dielectric cooling liquid.

8. The heat dissipating system according to claim 6, wherein the condenser is a heat pipe, which is disposed at a side of the evaporator, extended at outside of the cooling tank and uncovered by the cooling tank, wherein the coolant in the heat pipe is phase-changed into the gaseous state and flows to outside of the cooling tank after absorbing thermal energy from the evaporator, and is phase-changed into the liquid state and flows to a section near the evaporator after dissipating heat energy to air.

9. The heat dissipating system according to claim 6, further comprising a first gas driving module disposed at outside of the cooling tank for driving air to flow around the condenser.

10. The heat dissipating system according to claim 9, further comprising a temperature sensor for, in accordance with a temperature measured by the temperature sensor, determining whether to turn on the first gas driving module or the second gas driving module, or adjusting a rotation speed of the first gas driving module or the second gas driving module.
